(19) United States
(12) Patent Application Publication
(10) Pub. No.: US 2010/0175741 A1
(43) Pub. Date: Jul. 15, 2010

(54) Dual Axis Sun-Tracking Solar Panel Array

(75) Inventor: Steve Thorne, Berkeley, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: John Danhakl, Pacific Palisades, CA (US)

(21) Appl. No.: 12/353,143

(22) Filed: Jan. 13, 2009

(51) Int. Cl. H01L 31/048

(52) U.S. Cl. 136/251

(57) ABSTRACT

Apparatuses are disclosed for adjusting the position of the photovoltaic panels. The adjustments of the photovoltaic panels can be performed in two axes: pivot and tilt. The photovoltaic panels can be pivotably mounted along the longitudinal axis of rotatable frames. The substantially parallel photovoltaic panels in a frame can be simultaneously pivoted by a pivoting drive mechanism attached to the frame. Multiple tiltable frames can be arranged in parallel to each other, thus creating a 2-D matrix of the photovoltaic panels. The tiltable frames can be supported by an elevated structure permitting the unobstructed rotation of both the frames and the panels inside the frames. A controller can synchronize the tilt and pivot, such that the combined rotation of the photovoltaic panels results in the photovoltaic panels of the entire array being substantially perpendicular to the incident solar radiation.

### BACKGROUND OF THE INVENTION

The present invention relates generally to sun-tracking systems for photovoltaic panels. More particularly, the sun-tracking systems adjust the orientation of the photovoltaic panels with respect to the incoming sunlight to increase the photovoltaic panels' solar irradiation, therefore increasing the amount of electrical energy produced by the photovoltaic panels.

Due to the concerns over global warming and the limited amount of fossil fuels, alternative methods of energy production are desired. One such alternative source of energy is the solar energy produced by photovoltaic solar panels, which utilize the photoelectric effect to convert the energy of sun's radiation into electricity. The performance of such photovoltaic panels is determined by two factors: their efficiency in converting the sunlight into energy and their orientation relative to the incident angle of the sunlight.

Significant research has been done toward increasing the conversion efficiency of the photovoltaic panels, which is presently about 6% to 17%. Regarding the photovoltaic panels' orientation, it is known that a perpendicular orientation of the panels to the incident angle of sunlight maximizes the solar irradiation of the panels, thus maximizing the total amount of solar energy converted to electrical energy. The incident angle of sunlight varies in the east-west direction as a function of the time of day and the north-south direction as a function of the time of year. Accordingly, sun-tracking devices that attempt to keep the photovoltaic panel position perpendicular to the direction of the sunlight at different times of day and year are often mechanically complex, expensive to manufacture, and prone to malfunctioning.

A variety of techniques for adjusting the position of the photovoltaic panels exist in the field. Some systems for changing the angle of the photovoltaic panels have the panels arranged in a 2-D matrix of columns and rows. These systems can adjust the panel angle about two axes. The photovoltaic panels are pivoted by a mechanism that has multiple drive bars and pivoting points. Furthermore, all the panels in a given column are mounted above a tilt axis which rotates both the panels and the associated pivoting mechanisms, thus adding complexity to an already intricate panel pivoting mechanism.

Some other systems for changing the angle of the photovoltaic panels have a solar tracking system that changes the solar panel angle in the north-south direction only. The east-west axis may only be adjusted manually at the installation time. Thus, these systems lack the ability to automatically adjust the east-west orientation of the photovoltaic panels to follow the direction of the sunlight during the day.

Some systems that can adjust the position of the photovoltaic panels in two directions are of the alt-azimuth type. With these systems, the entire 2-D matrix of photovoltaic panels is mounted on a large rotating table that rotates in a plane parallel to the ground. Additional rotation is provided per individual panel or per panel group. With these systems the mechanism for rotating the table tends to be mechanically complex, subjected to high mechanical loads, and expensive.

Some other systems are roof mountable and can rotate the photovoltaic panels around two axes. The photovoltaic panels are rotated in the first direction through a centrally mounted motor and a suitable mechanical linkage. However, the rotation in the second direction is provided by hinging one side of the system frame to the surface (usually the roof), coupled with the elevation of the other side by a motorized rack and pinion. Thus, the range of the angles achievable in the second direction is limited.

Therefore, a need remains for systems that can adjust the angle of the photovoltaic panels in two directions, while being capable of withstanding high mechanical loads and providing a wide range of rotation angles.

### BRIEF SUMMARY OF THE INVENTION

The present invention relates to systems for adjusting the position of the photovoltaic panels such that they can be perpendicular to the incident sunlight. The orientation of the photovoltaic panels can be controlled about two axes to provide for separate pivot and tilt movements. The photovoltaic panels can be pivotably mounted along the longitudinal axis of tiltable frames. The substantially parallel photovoltaic panels in a frame can be simultaneously pivoted by a pivoting drive mechanism attached to the frame. Multiple tiltable frames can be arranged parallel to each other, thus creating a 2-D matrix of photovoltaic panels. The tiltable frames can be supported by an elevated structure permitting the unobstructed rotation of both the frames and the panels inside the frames. The frames can be tilted by a per-frame mechanism or a mechanism that is common to multiple frames. A controller can synchronize the tilt and pivot, such that the combined rotation of the photovoltaic panels results in the photovoltaic panels of the entire array being substantially perpendicular to the incident solar radiation. The system can track the position of the sun using solar intensity sensors or a table of sun positions to continuously maintain the perpendicularity of the photovoltaic panels with respect to the incident sunlight.

In one embodiment, an apparatus for controlling the orientation of photovoltaic panels has a plurality of photovoltaic panels having panel faces for producing an electrical current when exposed to sunlight. The photovoltaic panels are arranged parallel to one another and pivotably mounted along a longitudinal axis. A frame is extended about the longitudinal axis and dimensioned for holding the photovoltaic panels parallel to one another. The frame has first orientation means configured to adjust a pivot angle of the photovoltaic panels of the frame, and second orientation means configured to adjust a tilt angle of the frame, thus adjusting the tilt angle of the photovoltaic panels mounted along a longitudinal axis of a frame.

In one aspect, the apparatus further has one or more frames arranged to have substantially parallel longitudinal axes. The first orientation means are configured to set the frames to substantially the same tilt angle, thus setting the photovoltaic panels in the frames to substantially the same tilt angle. The apparatus also has girders to hold the frames in a common structure, and the support configured for attaching the apparatus with a base surface.

In another aspect, the apparatus has the first orientation means to adjust the pivot angle of the photovoltaic panels in all the frames to substantially the same value.

In yet another aspect, the apparatus has the second orientation means to adjust the tilt angle of all the frames to substantially the same value.

In another aspect, the apparatus further has a controller configured to coordinate the first orientation means and the second orientation means such that the resulting orientation of the panel faces is substantially perpendicular to the direction of sunlight.

In another aspect, the apparatus has a measurement device configured to measure the direction of the sunlight and to provide the measured direction to the controller.

In another aspect, the apparatus has an energy metering device configured to measure the energy produced by the photovoltaic panels.

In another embodiment, an apparatus for controlling the orientation of photovoltaic panels has a frame extending about a longitudinal axis and dimensioned for holding the photovoltaic panels parallel to one another. The frame further has a plurality of panel holders configured to pivotably hold the photovoltaic panels, and first orientation means configured to adjust a pivot angle of the photovoltaic panels of the frame. Second orientation means are configured to adjust a tilt angle of the frame, thus adjusting the tilt angle of the photovoltaic panels held by the holders along the longitudinal axis of a frame.

For a further understanding of the nature and advantages of the invention, reference should be made to the following description taken in conjunction with the accompanying figures. It is to be expressly understood, however, that each of the figures is provided for the purpose of illustration and description only and is not intended as a definition of the limits of the embodiments of the present invention.

### BRIEF DESCRIPTION OF THE DRAWINGS

FIG. 1 is a diagram of the solar energy incident on a photovoltaic panel.

FIG. 2 is a schematic drawing illustrating geometrical relationships between the panels and a frame in a photovoltaic panel positioning apparatus in accordance with one embodiment of the present invention.

FIG. 3 is a perspective view illustrating a frame and a frame tilting mechanism in accordance with one embodiment of the invention.

FIG. 4 is a perspective view illustrating the photovoltaic panels arranged in multiple frames in accordance with one embodiment of the invention.

FIG. 5a is a partial perspective view illustrating a chain and sprocket tilting mechanism for the tilting of frames.

FIG. 5b is a partial perspective view illustrating a gear mechanism for the tilting of the frames.

FIG. 6 is a partial perspective view illustrating a chain and sprocket mechanism for pivoting the photovoltaic panels in a frame.

FIGS. 7a and 7b show side views of two positions of the photovoltaic panels driven by a linear actuator mechanism.

### DETAILED DESCRIPTION OF THE INVENTION

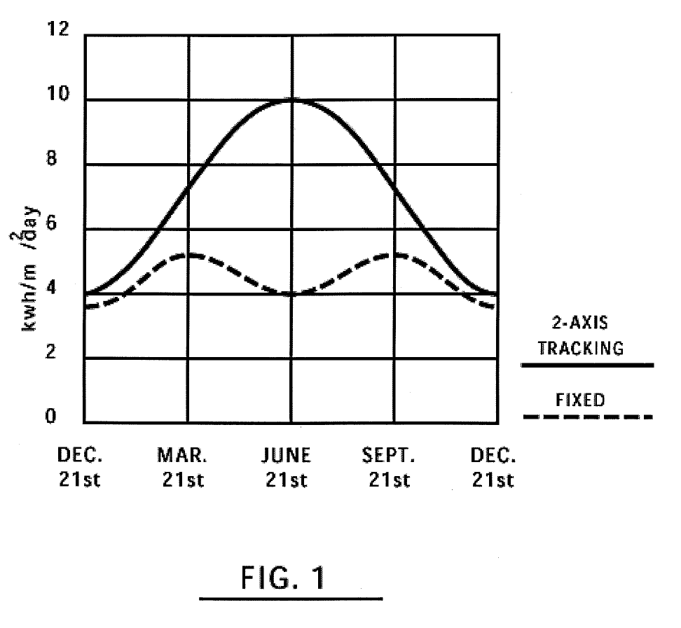

The present invention relates to the systems for adjusting the position of the photovoltaic panels such that they can be perpendicular to the incident sunlight. The orientation of the photovoltaic panels can be controlled about two axes to provide for separate pivot and tilt movements. The photovoltaic panels can be pivotably mounted along the longitudinal axis of tiltable frames. The substantially parallel photovoltaic panels in a frame can be simultaneously pivoted by a pivoting drive mechanism attached to the frame. Multiple tiltable frames can be arranged parallel to each other, thus creating a 2-D matrix of photovoltaic panels. The tiltable frames can be supported by an elevated structure permitting the unobstructed rotation of both the frames and the panels inside the frames. The frames can be tilted by a per-frame mechanism or a mechanism that is common to multiple frames. A controller can synchronize the tilt and pivot, such that the combined rotation of the photovoltaic panels results in the photovoltaic panels of the entire array being substantially perpendicular to the incident solar radiation. The system can track the position of the sun using solar intensity sensors or a table of sun positions to continuously maintain the perpendicularity of the photovoltaic panels with respect to the incident sunlight. The details of the exemplary embodiments of the present invention are explained with reference to FIGS. 1-6.

FIG. 1 shows a graph of the solar energy per incident area as a function of the time of year. The dashed line represents the solar energy irradiation for a photovoltaic panel having a fixed position, while the solid line corresponds to a photovoltaic panel that tracks the position of sun, thus maintaining the perpendicular orientation of the photovoltaic panel against the direction of sunlight at different times of day and year. The area between the two lines corresponds to the solar energy that was available during the year, but was not received by the photovoltaic panel due to its non-perpendicular orientation against the direction of sunlight. Therefore, the area between the two lines represents lost opportunity to acquire solar energy. Hence, the systems that position the photovoltaic panels perpendicular to the direction of sunlight can capture the lost potential.

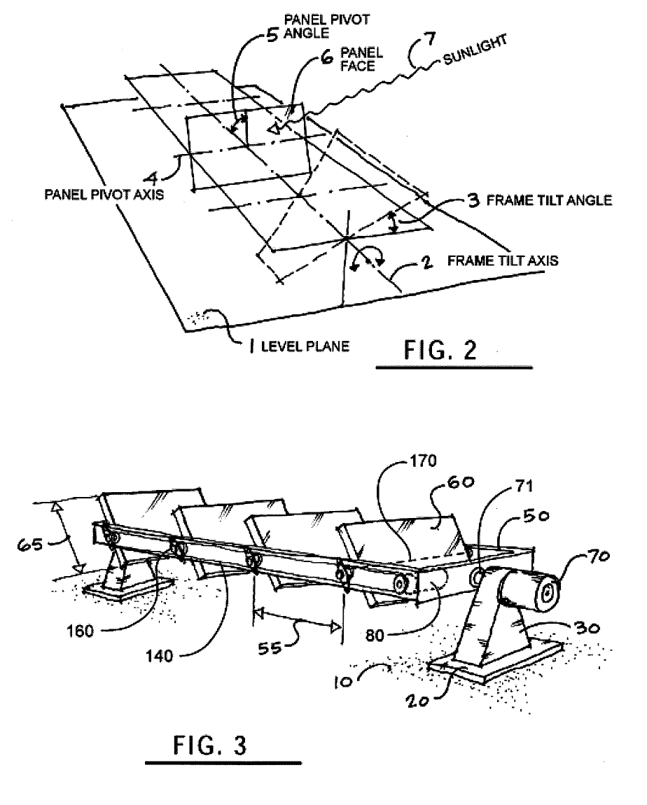

FIG. 2 shows the geometrical relationships between the frame tilt axis 2 and panel pivot axis 4. In this embodiment, frame tilt axis 2 is perpendicular to panel pivot axis 4, while both axes are substantially parallel to level plane 1, which can represent the ground or roof where the system is mounted. Frame tilt axis 2 and panel pivot axis 4 both pass through the photovoltaic panels. Panel pivot axes 4 are substantially parallel to each other for the photovoltaic panels in the frame.

FIG. 2 also shows frame tilt angle 3 and panel pivot angle 5, which are defined with respect to frame tilt axis 2 and panel pivot axis 4, respectively. Rotation of the frame around frame tilt axis 2 tilts all the photovoltaic panels in the frame by the same frame tilt angle 3. Proper synchronization of frame tilt angle 3 and panel pivot angle 5 results in panel face 6 being exposed substantially perpendicularly to the direction of incoming sunlight 7, thus maximizing the solar irradiation on the photovoltaic panel and, consequently, generating maximum electrical power from the photovoltaic panel. The synchronization can be done using tables of frame tilt angle 3 and panel pivot angle 5 that maximize the incoming solar irradiation for the different times of day and year. The tables of solar irradiation angles are widely available. An example of such tables is given in Table 9.1.4 on page 9-13 of Marks' Standard Handbook for Mechanical Engineers by Eugene A. Avallone, Theodore Baumeister, Ali Sadegh, and Lionel Simeon Marks (McGraw-Hill Professional, 2006, ISBN 0071428674). Other synchronization methods can involve solar irradiation sensors capable of determining the angle of solar irradiation. An example of such a solar irradiation sensor capable of automatically determining its position through a Global Positioning System and then calculating the angle of solar irradiation is the Wheeler Sunpredictor™ by LISTECH from Windsor, Australia. A person skilled in the art of solar sensor would know of many other devices for determining the angle of solar irradiation. Tabulated or measured values of the angle of solar irradiation can be used by a controller to calculate the appropriate panel pivot angle 5 and frame tilt angle 3, thus resulting in the panel face 6 being substantially perpendicular to the direction of the solar irradiation. For instance, an industrial controller or a general purpose computer can be used to control panel pivot angle 5 and frame tilt angle 3 by sending control signals to the drive motors for pivoting of the photovoltaic panels and tilting of the frames.

FIG. 3 is a perspective view of frame 50 having a plurality of photovoltaic panels 60 mounted substantially parallel to each other and disposed along the longitudinal axis of frame 50. The photovoltaic panels come in different sizes and different electricity generating potentials. Some examples of the photovoltaic panels are PV-UD185MF5 by Mitsubishi Solar and KD180GX-LP by Kyocera. Many other photovoltaic panels are available on the market. The photovoltaic panels can be held within a frame by grippers or holders, like, for example, Toggle Clamp 3CWX4 or Latch Clamp 3CXE4 by Grainger. Many other panel grippers and holders are available on the market.

Still referring to FIG. 3, panel spacing 55 is preferably greater than photovoltaic panel height 65 so as to minimize the shadowing that one photovoltaic panel casts on another when the sunlight angle is low. Furthermore, the elevation of frame 50 above base surface 10 is preferably selected to allow for the full revolution of the photovoltaic panels around their respective panel pivot axes 4. Panel shaft 170 substantially defines the pivot axis. The panel pivot for all photovoltaic panels 60 in frame 50 can be controlled simultaneously by motorized panel drive 80, since each photovoltaic panel 60 has panel shaft 170 for supporting panel sprocket 160, and all the panel sprockets can be driven by panel drive 80 using panel chain 140.

FIG. 3 also shows motorized frame drive 70 for frame 50 tilting. Frame drive 70 provides torque to frame shaft 71 for the frame rotation. Frame shaft 71 defines the frame tilt axis, which passes through frame 50 and photovoltaic panels 60 mounted in the frame. A combined action of panel drive 80, which adjusts the pivot angle of photovoltaic panels 60, and frame drive 70, which adjusts the tilt angle of frame 50, results in the perpendicular orientation of photovoltaic panels 60 with respect to the incident sunlight. Frame shaft 71 on one side of frame 50 and a frame shaft (not shown) on the opposite side of the frame are mounted on the opposing supports 30, each having base 20 for attachment with a fixed base surface 10. The height of support 30 and base 20 can be selected such as to assure clearance of photovoltaic panels 60 against the base surface. Preferably, frame shaft 71 is oriented parallel to the earth's north-south axis, thus requiring less frequent frame tilt angle adjustment compared to the panel pivot angle adjustment. FIG. 3 shows a single frame 50 being rotated by frame drive 70. It should be recognized that the invention embodiments having multiple frames being driven by one frame drive 70 can be envisioned without departing from the above-described concepts.

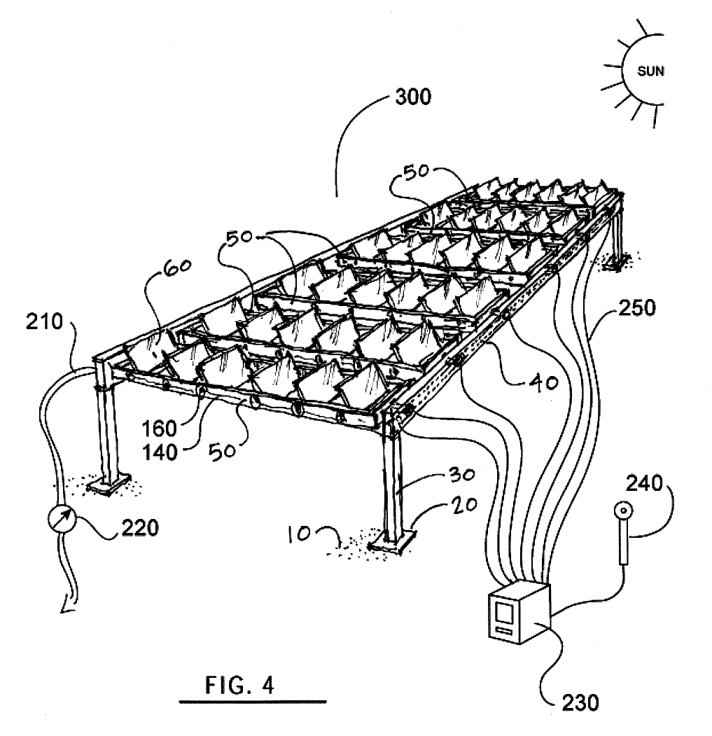

FIG. 4 is a perspective view of panel orientation apparatus 300 which has photovoltaic panels 60 arranged in an array of substantially parallel frames 50. Frames 50 can be mounted on a pair of substantially parallel girders 40, which rest on supports 30 and bases 20, thus attaching panel orientation apparatus 300 to base surface 10. Photovoltaic panels 60 in each frame can be pivoted by panel drive 80 (shown in FIG. 2) through chain 140 and sprockets 160, thus adjusting the panel pivot angle for all photovoltaic panels 60 in a given frame. Furthermore, frames 50 do not have to be parallel to base surface 10. It might be advantageous in some locations to elevate one of the supporting girders 40 along one line of columns 30 higher than the opposing girder if, for instance, angle adjustment apparatus 300 is mounted on a roof or over sloped ground. The frames may be rigid such that the photovoltaic panel weight causes the frames to deflect less than some threshold value, for example 2% of the frame longitudinal length or less than the distance to the base surface 10, thus assuring that the frames can freely tilt without interfering with the base surface.

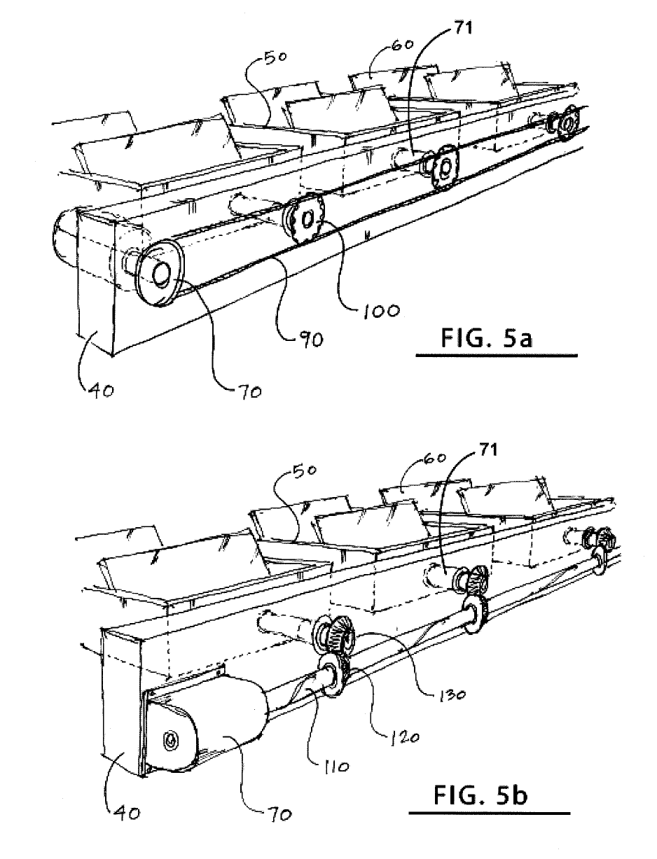

Panel orientation apparatus 300 can also have conductor wires 210 for transferring the electrical current generated by the photovoltaic panels off the apparatus to the electrical grid. The power delivered to the electrical grid can be metered by metering device 220, which may measure either the total energy generated by the photovoltaic panels or the energy generated by a group of the photovoltaic panels or a single photovoltaic panel or a fraction of photovoltaic panel. Irradiation sensor 240 detects the direction of the sunlight and can be connected to controller 230, which can calculate the required control parameters for the frame drive and panel drive. The required parameters include the final position of the shafts of the frame and panel drives. Controller 230 can send control signals to the frame drive and panel drive through control wires 250. The electrical energy produced by the photovoltaic panels can also be used to power controller 230 and metering device 220, but they can also be powered externally. The adjustment of the frame tilt angle is shown with reference to FIGS. 5a and 5b below.

FIG. 5a shows an embodiment of a tilt angle adjusting mechanism that can simultaneously change the tilt angle for all the frames in the panel orientation apparatus 300. Frames 50 are mounted on girder 40 using frame shafts 71. Frame sprocket 100 can be fixedly connected to each frame shaft 71 for the tilting of frame 50. The tilt angle of frames 50 can be changed by frame drive 70, which provides torque to frame sprockets 100 through frame drive chain 90 that connects all frame sprockets 100 to frame drive 70.

FIG. 5b shows another embodiment of the tilt angle adjusting mechanism that uses a single frame drive 70 to change the tilt angle. With this embodiment, frames 50 have frame gears 130 fixedly attached to frame shafts 71. Frame gears 130 engage with drive gears 120, which are fixedly attached to driveshaft 110. Frame drive 70 rotates driveshaft 110 and drive gears 120 attached thereto, which, in turn, rotate frame gears 130, thus adjusting the tilt angle of the frames. The amount of tilt is based on the control signal received from the controller. Other mechanisms for the adjustment of frames' tilt angles are possible, like, for instance, rack and pinion, belt and pulley, worm drive, and hydraulic or pneumatic cylinders, or a combination of different mechanisms. A dedicated frame drive 70 per each frame 50 or a group of frames is also possible.

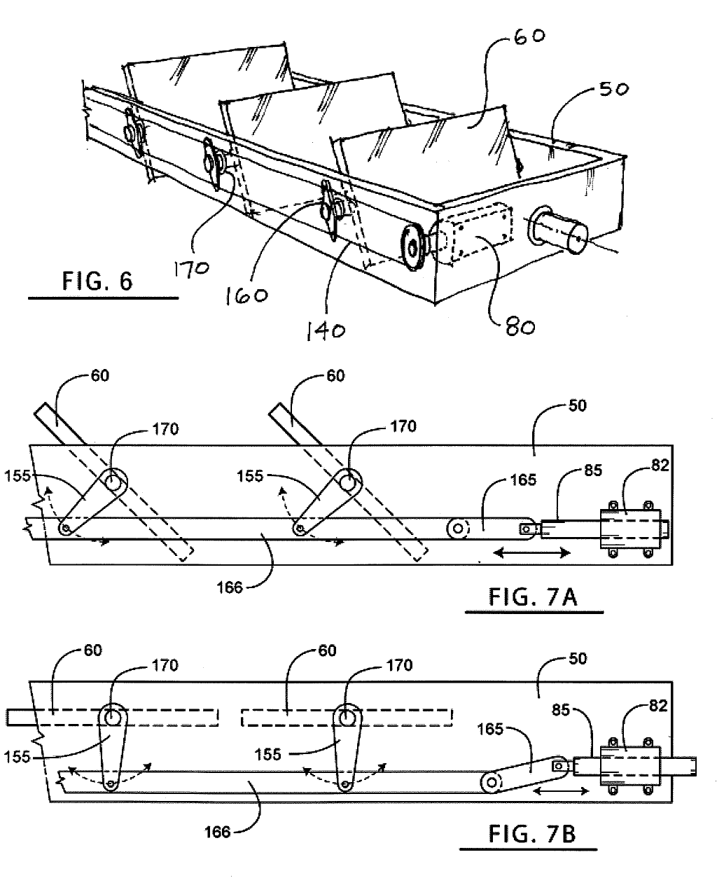

FIG. 6 is a perspective view of one embodiment of a mechanism for adjusting the panel pivot angle. With this embodiment, each panel shaft 170 has a fixedly attached panel sprocket 160. The panel sprockets are connected with panel drive 80 by panel chain 140. Panel drive 80 provides torque, which is transferred to all panel sprockets 160 in the frame by panel chain 140, thus pivoting photovoltaic panels 60 to a desired pivot angle.

FIGS. 7a and 7b show another embodiment of a mechanism for adjusting the panel pivot angle. Here, one end of raiser arm 155 is fixedly connected with panel shaft 170, while the opposite end of the raiser arm is pivotably connected with linear bar 166. As linear bar 166 moves (left and right as shown on FIGS. 7a and 7b), raiser arm 155, being fixed to panel shaft 170, rotates the panel shaft, thus changing the pivot angle of the photovoltaic panel attached to the panel shaft. Linear bar 166 can be set in motion by connecting bar 165 that connects to linear actuator mechanism 82 through actuator bar 85. Linear actuator mechanism 82 can be a worm driven gear box assembly having a high gear ratio. Many worm driven gear box assemblies that produce linear motion are available on the market. One example is Action Jac™ linear actuator by Nook Industries, Inc., Ohio. Other mechanisms for pivoting photovoltaic panels 60 are possible. One example is an engagement of the gears on a driveshaft connected to panel drive 80 with the respective gears on each of the panel shafts. Other examples of the mechanisms for adjusting the panel pivot angle are rack and pinion, belt and pulley, and hydraulic or pneumatic cylinder drives, or a combination of different mechanisms.

As will be understood by those skilled in the art, the present invention may be embodied in other specific forms without departing from the essential characteristics thereof. For example, the frame drive and the panel drive may receive electrical energy directly from the photovoltaic panels. Furthermore, the frames may host different numbers of photovoltaic panels having differing sizes. Many other embodiments are possible without deviating from the spirit and scope of the invention. These other embodiments are intended to be included within the scope of the present invention, which is set forth in the following claims.

What is claimed is:

1. An apparatus for controlling the orientation of photovoltaic panels, comprising:
a plurality of photovoltaic panels having panel faces for producing an electrical current when exposed to sunlight, said photovoltaic panels arranged parallel to one another and pivotably mounted along a longitudinal axis;
a frame extending about said longitudinal axis and dimensioned for holding the photovoltaic panels parallel to one another, said frame comprising first orientation means configured to adjust a pivot angle of the photovoltaic panels of the frame; and
second orientation means configured to adjust a tilt angle of the frame, thus adjusting the tilt angle of the photovoltaic panels mounted along a longitudinal axis of a frame.

2. The apparatus of claim 1, wherein said frame is one of a plurality of said frames arranged to have substantially parallel longitudinal axes, wherein said second orientation means are configured to set the frames to substantially the same tilt angle, thus setting the photovoltaic panels in the frames to substantially the same tilt angle,
girders to hold said plurality of frames in a common structure; and
a support configured for attaching the apparatus with a base surface.

3. The apparatus of claim 2, wherein the second orientation means comprise:
a frame drive attached to the girders and configured to provide torque upon receiving a signal;
a driveshaft attached with the frame drive and configured to transmit the torque from the frame drive;
a plurality of drive gears distributed along the driveshaft;
a plurality of frame gears each attached with a frame and each engaging with a mating drive gear to change the tilt angle of the frame as the driveshaft rotates.

4. The apparatus of claim 2, wherein the second orientation means comprise:
a frame drive attached to a girder and configured to provide torque upon receiving a signal;
a driving sprocket attached with the frame drive and configured to transmit the torque from the frame drive;
a plurality of driven sprockets each attached with a frame and configured to change the tilt angle of the frame as the driving sprocket rotates; and
a chain configured to engage with the driving sprocket and the driven sprockets, thus transmitting torque from the driving sprocket to the driven sprockets to change the tilt angle of the frame.

5. The apparatus of claim 2, wherein the second orientation means comprise an assembly selected from a group consisting of rack and pinion, belt and pulley, worm drive, hydraulic cylinder, and pneumatic cylinder, or a combination thereof.

6. The apparatus of claim 1, wherein the first orientation means comprise:
a panel drive attached to the frame and configured to provide torque upon receiving a signal;
a driving sprocket attached with the panel drive and configured to transmit the torque from the panel drive;
a plurality of driven sprockets each attached with a photovoltaic panel and configured to change the tilt angle of the photovoltaic panel as the driving sprocket rotates; and
a chain configured to engage with the driving sprocket and the driven sprockets for transmitting torque from the driving sprocket to the driven sprockets to change the pivot angles of the photovoltaic panels.

7. The apparatus of claim 1, wherein the first orientation means comprise:
a linear actuator attached to the frame and configured to provide linear actuation in a substantially longitudinal direction of the frame upon receiving a signal;
a linear bar attached with an actuator bar of the linear actuator; and
a raiser arm pivotably attached with the linear bar on one side and fixedly attached with a panel shaft on the opposite side, wherein said raiser arm transfers a substantially linear motion of the linear bar to a rotational motion of the panel shaft, thus changing the pivot angle of the photovoltaic panel attached to the panel shaft.

8. The apparatus of claim 1, wherein the first orientation means comprise an assembly selected from a group consisting of engaging gears, rack and pinion, belt and pulley, worm drive, hydraulic cylinder, and pneumatic cylinder, or a combination thereof.

9. The apparatus of claim 2, wherein said first orientation means adjust the pivot angle of the photovoltaic panels in all said frames to substantially the same value.

10. The apparatus of claim 2, wherein said second orientation means adjust the tilt angle of all said frames to substantially the same value.

11. The apparatus of claim 2, wherein said support is configured to permit said frame to assume any tilt angle while being unobstructed by the base surface.

12. The apparatus of claim 1, wherein a gravitationally induced deflection of the frame is smaller than the distance between the undeflected frame and a base surface.

13. The apparatus of claim 1, wherein a gravitationally induced deflection of the frame is smaller than 2% of a longitudinal length of the frame.

14. The apparatus of claim 1, wherein said frames are tilted about an axis passing through the frame and being substantially parallel to the base surface.

15. The apparatus of claim 2, further comprising a controller configured to coordinate said second orientation means and said first orientation means such that the resulting orientation of the panel faces is substantially perpendicular to the direction of sunlight.

16. The apparatus of claim 15, wherein said controller comprise a computer configured to compute said resulting orientation of the panel faces from pre-programmed data about the position of Sun relative to latitudinal and longitudinal position of the apparatus.

17. The apparatus of claim 15, further comprising a measurement device configured to measure the direction of the sunlight and to provide the measured direction to said controller.

18. The apparatus of claim 1, further comprising conducting wires configured to transfer the electrical current generated by said panel faces off the apparatus.

19. The apparatus of claim 1, further comprising an energy metering device configured to measure energy produced by said photovoltaic panels.

20. The apparatus of claim 19, wherein said energy metering device is configured to measure energy produced by an individual photovoltaic panel or by a group of the photovoltaic panels.

21. An apparatus for controlling the orientation of photovoltaic panels, comprising:
a frame extending about a longitudinal axis and dimensioned for holding the photovoltaic panels parallel to one another, said frame further comprising:
a plurality of panel holders configured to pivotably hold the photovoltaic panels, and
first orientation means configured to adjust a pivot angle of the photovoltaic panels of the frame; and
second orientation means configured to adjust a tilt angle of the frame, thus adjusting the tilt angle of the photovoltaic panels held by the holders along the longitudinal axis of a frame.
